(19) United States
(12) Patent Application Publication
(10) Pub. No.: US 2013/0252406 A1
(43) Pub. Date: Sep. 26, 2013

(54) Techniques for drying and annealing thermoelectric powders

(71) Applicant: EVIDENT TECHNOLOGIES, INC., Troy, NY (US)

(72) Inventors: Clinton T. Ballinger, Ballston Spa, NY (US); Adam Z. Peng, Guilderland, NY (US); Susanthri Perera, Latham, NY (US); Dave Socha, Glenmont, NY (US)

(73) Assignee: Evident Technologies, Inc., Troy, NY (US)

(21) Appl. No.: 13/849,692

(22) Filed: Mar. 25, 2013

Related U.S. Application Data
(60) Provisional application No. 61/614,719, filed on Mar. 23, 2012.

(51) Int. Cl. H01L 21/02

(52) U.S. Cl. CPC H01L 21/02672
USPC 438/486

(57) ABSTRACT

Embodiments of the invention include a method of producing a low contaminant, stoichiometrically controlled semiconductor material, the method comprising providing a colloidal suspension of a plurality of colloidally grown semiconductor nanocrystals, providing an inorganic ligand structure around a surface of the semiconductor nanocrystals of the plurality of semiconductor nanocrystals, drying the colloidal suspension into a powder, and pre-annealing the powder into a semiconductor material.

### CROSS-REFERENCE TO RELATED APPLICATIONS

This application claims the benefit of co-pending U.S. Provisional Application Ser. No. 61/614,719, filed 23 Mar. 2012, which is hereby incorporated by reference herein.

### FIELD OF THE INVENTION

Embodiments of the present invention relate generally to methods of drying and annealing thermoelectric powders to improve the stoichiometry, purity, and performance of the materials.

### BACKGROUND OF THE INVENTION

Semiconductor materials have been used in a broad range of applications including, but not limited to, logic gates, sensors, solar cells, and many other applications. These materials form the backbone of modern electronic applications. Semiconductor nanomaterials, including nanocrystals, can have many additional benefits beyond those of other semiconductor materials.

One interesting field of study is in determining the optimal material systems for thermoelectric applications. It would appear that the ideal electronic structure includes a discrete distributed density of electron states. While it has been thought that a nanostructured material which is constructed of discrete semiconductor nanocrystals may exhibit such a discrete density, creating and testing such a material has proven very difficult. This has been largely due to the fact that, typically, nanocrystals are connected using organic surface molecules to “glue” them into a monolithic nanostructure. These organic interconnects between the discrete nanocrystals greatly reduce the electrical conductivity and seem to lead to poor overall material performance.

### SUMMARY OF THE INVENTION

A first aspect of the present invention includes a method of producing a low contaminant, stoichiometrically controlled semiconductor material, the method comprising: providing a colloidal suspension of a plurality of colloidally grown semiconductor nanocrystals; providing an inorganic ligand structure around a surface of the semiconductor nanocrystals of the plurality of semiconductor nanocrystals; drying the colloidal suspension into a powder; and pre-annealing the powder into a semiconductor material.

### DETAILED DESCRIPTION OF THE INVENTION

It has been proposed that nanostructured thermoelectric materials could significantly reduce the thermal conductivity of a structured material as compared to prior methods, due to increased phonon scattering at the grain boundaries. Furthermore, quantum confinement effects can also improve the Seebeck coefficient and electrical resistivity of the structured material. The previously mentioned ‘ideal electronic structure’ which includes a discrete distributed density of electron states may be best approximated by a nanostructured material that is constructed of discrete semiconductor nanocrystals.

In one embodiment, a newly developed special surface chemistry can aid in eliminating the problems regarding the properties of nanomaterials with organic surface molecules. For instance by using short chain inorganic surface ligands, instead of the traditional organic molecules, as the “glue” of the system may eliminate the reduction in electrical conductivity and the poor material performance. The new ligand system of the surface chemistry, in this embodiment, may enable a new technology for producing high quality electronically coupled materials. This ligand system is unique in that purely inorganic, metal chalcogenide complexes are used to passivate the surface of the colloidal nanocrystals used in the nanostructured material. Many inorganic ligands may be used in this embodiment. Some non-limiting examples of inorganic ligand structures, according to some embodiments, may include sulfur, carbon, hydrocarbons, and excess tellurium.

To date, this methodology is the first such known to produce both films and bulk structures from colloidal nanoparticles that have transport properties useful for electronic applications while still maintaining their low dimensional properties. Unlike other previous technologies utilizing colloidal nanoparticles, this approach does not rely on organic materials to provide electronic coupling between the nanoparticles. As a result, in methods according to current embodiments, the operating temperature of the resulting material is not limited by decomposition of organic molecules.

In one embodiment, a method is disclosed for producing semiconductor materials. According to the embodiment, the material may be treated with heat, vacuum, or a combination of both heat and vacuum. The heating may be from about 100° C. to 300° C. The pressure applied can include any pressure typically used for such materials. Further, another embodiment may utilize an inert gas overpressure. This step may be referred to as a pre-annealing step, as it is in preparation for annealing the material. In some embodiments, the process may include first using a drying procedure prior to any pre-annealing procedures. The drying step allows for the removal of any solvents remaining following the synthesis or storage of the semiconductor nanocrystals. Any known drying methods may be utilized. Following drying of the semiconductor nanocrystals, the pre-annealing step can be utilized. This pre-annealing step may be used in order to drive off any undesirable components in the material, which may have been absorbed or attached to the surface of the nanocrystals. The undesirable components may be excess materials used in synthesis, or impurities within the materials utilized.

The treatment process according to embodiments of the current invention can target moieties that have a high vapor pressure. As such, the inorganic ligand structure moieties, which typically have a high vapor pressure, may be partially, or evenly entirely, removed. For example, when using excess tellurium as the ligand, which has a relatively high vapor pressure, the heat and/or vacuum treatment can remove nearly all, or all of the excess tellurium. As an added benefit to this process, when synthesizing certain semiconductor nanocrystals using colloidal chemistry methodologies, one example of which is BiSbTe, an excess of one of the elements is often a result of the reaction, tellurium in the case of BiSbTe. As a result, use of the excess element, such as tellurium, can be an efficient choice for a ligand structure to be used with the semiconductor nanocrystals, as it may also be easy to remove using the disclosed treatment process.

A drying procedure may be used before the pre-annealing step, as mentioned above. The drying process can include heating the colloidal suspension of nanocrystals, for instance up to about 120° C. Alternatively, this drying process may use centrifugation, rather than heat, to separate the colloidally grown semiconductor nanocrystals from the liquid solvent. The centrifugation step may produce a wet powder in the bottom of the centrifuge tube, which can then be removed and placed in a drying dish where the wet nanocrystals may be spread out to increase the surface area in an effort to encourage evaporation of the residual solvent, perhaps also in the presence of heat. In addition, this drying step may also be performed in a vacuum environment in order to increase the evaporation rate.

The pre-annealing step can reduce the contamination levels as well as aid in controlling the stoichimetry of the material. In addition, it leads to crystallization of the ensemble of dry semiconductor nanocrystals, which can ensure formation of the correct lattice structure of the crystals, as well as push non-stoichiometric excess reactants out of the material. In essence, this step reconstitutes the semiconductor nanocrystals such that they are recrystalized.

After the material has been pre-annealed as described above, the process may further include a washing step for the pre-annealed material. Any known washing methods may be utilized. In one embodiment, a hydrazine wash may be utilized. In this case, the material can be soaked in hydrazine for about an hour, and up to approximately a day. In another embodiment, trioctylphosphine may be utilized to wash the pre-annealed material. These washing steps can reduce any unwanted material or contaminants that may still be present in the material. In a further embodiment, after the material has been washed, the resulting material may be dried a second time, in one example by heating the material to about 100° C. In yet another further embodiment, the material may be pre-annealed following the above description after the washing step, or even after the further drying step after the wash. Accordingly, any number and combination of these processes may be utilized

The described method allows for, via the pre-annealing step, a crystallization or recrystallization of the semiconductor nanocrystals such that they may be reconstituted into a natural lattice structure for the chosen nanocrystal material. It also assures proper stoichiometry of the resulting lattice structure. The combined method can also effectively remove any volatile solvents and relatively high vapor pressure contaminants.

This procedure is particularly suited for thermoelectric materials, in one embodiment. The overall effect of removing the ligand structure, for example, the excess tellurium, is to lower the charge carrier concentration, which typically improves the Seebeck coefficient. Removing residual sulfur, or other ligands of choice, also improves the Seebeck coefficient, particularly for a p-type material. In a thermoelectric embodiment, this material may, for instance, then be hot-pressed by any now known or later developed method to form a pellet suitable for thermoelectric applications. However, this procedure can also be applicable for applications other than thermoelectric materials as a general methodology to control the stoichimetry and contamination levels of a semiconductor material. This is important in nearly all solid state applications.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed:

1. A method of producing a low contaminant, stoichiometrically controlled semiconductor material, the method comprising:
providing a colloidal suspension of a plurality of colloidally grown semiconductor nanocrystals;
providing an inorganic ligand structure around a surface of the semiconductor nanocrystals of the plurality of semiconductor nanocrystals;
drying the colloidal suspension into a powder; and
pre-annealing the powder into a semiconductor material.

2. The method of claim 1, further comprising:
washing the semiconductor material.

3. The method of claim 2, wherein the washing comprises soaking the semiconductor material in hydrazine.

4. The method of claim 2, further comprising:
drying the semiconductor material with heat.

5. The method of claim 1, wherein the drying comprises heating the colloidal suspension.

6. The method of claim 1, wherein the drying comprises centrifuging the colloidal suspension into a centrifuged material.

7. The method of claim 6, further comprising:
placing the centrifuged material into a vacuum and allowing any moisture to evaporate.

8. The method of claim 1, wherein the inorganic ligand structure is chosen from a group consisting of: sulfur, carbon, hydrocarbons, and excess tellurium.

9. The method of claim 1, wherein the pre-annealing step comprises exposing the powder to heat, a vacuum, or both.

10. The method of claim 1, wherein the pre-annealing allows the semiconductor nanocrystals to recrystalize with an aligned lattice structure and a controlled stoichiometry.
